(19) United States
(12) Patent Application Publication
(10) Pub. No.: US 2009/0029541 A1
(43) Pub. Date: Jan. 29, 2009

(54) METHOD OF FABRICATING ANTI-FUSE AND METHOD OF PROGRAMMING ANTI-FUSE

(75) Inventors: Kuang-Yeh Chang, Hsinchu (TW); Shing-Ren Sheu, Hsinchu City (TW); Chung Jen Ho, Taoyuan County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 12/211,608

(22) Filed: Sep. 16, 2008

Related U.S. Application Data
(62) Division of application No. 11/782,154, filed on Jul. 24, 2007.

(51) Int. Cl. H01L 21/44

(52) U.S. Cl. 438/600

(57) ABSTRACT

A method of fabricating an anti-fuse includes firstly forming a dielectric layer on a substrate having a first conductive type. Next, a conductive layer is formed on the dielectric layer. A first ion implantation process is then performed, such that the conductive layer has the first conductive type. Thereafter, the conductive layer and the dielectric layer are patterned to form a gate and a gate dielectric layer. The gate and the gate dielectric layer together construct a gate structure. Finally, two source/drain regions having a second conductive type are formed in the substrate at respective sides of the gate. Besides, a method of programming an anti-fuse includes firstly applying a voltage to a gate to break down a gate dielectric layer. The gate and a substrate are then electrically conducted or a P/N forward bias is then formed in a P/N junction after the breakdown of the gate dielectric layer.

### CROSS-REFERENCE TO RELATED APPLICATION

This application is a divisional of an application Ser. No. 11/782,154, filed on Jul. 24, 2007, now pending. The entirety of each of the above-mentioned patent applications is hereby incorporated by reference herein and made a part of this specification.

### BACKGROUND OF THE INVENTION

1. Field of the Invention

The present invention relates to an integrated circuit device, a method of fabricating the same, and a method of programming the same. More particularly, the present invention relates to an anti-fuse, a method of fabricating the same, and a method of programming the same.

2. Description of Related Art

Fuses and anti-fuses are extensively applied to integrated circuits for disabling the circuits when defects thereof are detected during inspection. Generally, the fuse is made of polysilicon or a metallic material. Furthermore, the common way to blow the fuse to form an open circuit is to employ a laser beam to burn out the fuse. Said fuse is the so-called laser fuse. However, being limited to a wavelength of the laser beam, a large surface area occupied by the laser fuse is indispensable. Moreover, after the chip is packed, the fuse cannot be blown for performing a subsequent programming process, and thus an application of the laser fuse is limited to some extent.

A typical anti-fuse is a capacitor formed by two conductive layers and a dielectric layer sandwiched therebetween. As the dielectric layer is not electrically conducted, the anti-fuse is in a default state, whereas the anti-fuse is in a programmed state when the dielectric layer is electrically conducted. A method of programming the anti-fuse may include applying a voltage sufficient for breaking down the dielectric layer, and thereby the two conductive layers are electrically conducted.

During the fabrication of the integrated circuit, a gate of a transistor, an insulating layer thereof, or an oxide layer or a silicon oxynitride layer formed by performing an in-situ process can all serve as the programmable anti-fuse. Besides, in a process of fabricating a semiconductor, a slightly-modified surface channel metal oxide semiconductor field effect transistor (MOSFET) can be used as the anti-fuse.

FIG. 1 is a schematic view illustrating an anti-fuse of a conventional N-type channel MOSFET.

Referring to FIG. 1, in an N-type channel MOSFET 10, a substrate 100 and a gate 104 may serve as two conductive layers of the anti-fuse, whereas a gate dielectric layer 102 may serve as an insulating layer. In a process of programming the anti-fuse, a positive voltage is applied to the gate 104 to break down the gate dielectric layer 102. As pinholes are punched by applying a high-voltage-programming pulse to the gate dielectric layer 102 nearby source/drain regions 106 and 116, a low resistive current path may be formed due to the fact that a conductive type of the gate 104 and the source/drain regions 106 and 116 is N-type. However, the gate 104 is N-type, and the substrate 100 is P-type. Thus, when the pinholes are punched by applying the high-voltage-programming pulse to the gate dielectric layer 102 above a channel, a P-N junction having a reverse bias is formed between the N-type gate 104 and the P-type substrate 100. A high resistive non-linear current path is then constructed. The non-linear current path is not apt to be detected by a sense amplifier, thus resulting in failure of the circuit. When the anti-fuse is applied to program the circuit, a plurality of the pinholes is very much likely to be formed above an channel of the NMOS transistor, significantly reducing yield of the programmed circuit.

### SUMMARY OF THE INVENTION

The present invention is directed to an anti-fuse which is able to prevent a high resistive non-linear current path from forming, and thus yield of a programmed circuit is improved.

The present invention provides an anti-fuse including a substrate having a first conductive type, a gate having the first conductive type, a gate dielectric layer, and two source/drain regions having a second conductive type. The gate is disposed over the substrate. The gate dielectric layer is sandwiched between the substrate and the gate. The two source/drain regions are disposed in the substrate at respective sides of the gate.

According to an embodiment of the present invention, in the anti-fuse, the first conductive type is P-type, whereas the second conductive type is N-type.

According to an embodiment of the present invention, in the anti-fuse, the first conductive type is N-type, whereas the second conductive type is P-type.

According to an embodiment of the present invention, in the anti-fuse, each of the two source/drain regions includes a lightly-doped region and a heavily-doped region, and the two lightly-doped regions are not overlapped to each other.

According to an embodiment of the present invention, in the anti-fuse, each of the two source/drain regions includes a lightly-doped region and a heavily-doped region, and the two lightly-doped regions are partially overlapped.

According to an embodiment of the present invention, in the anti-fuse, the two lightly-doped regions are partially overlapped in the substrate below the gate.

According to an embodiment of the present invention, the anti-fuse further includes a spacer disposed on a sidewall of the gate.

The present invention further provides a method of fabricating an anti-fuse. The method includes firstly forming a dielectric layer on a substrate having a first conductive type. Next, a conductive layer is formed on the dielectric layer. A first ion implantation process is then performed, such that the conductive layer has the first conductive type. Thereafter, the conductive layer and the dielectric layer are patterned to form a gate and a gate dielectric layer. The gate and the gate dielectric layer together construct a gate structure. Finally, two source/drain regions having a second conductive type are formed in the substrate at respective sides of the gate.

According to an embodiment of the present invention, in the method of fabricating the anti-fuse, the first conductive type is P-type, whereas the second conductive type is N-type.

According to an embodiment of the present invention, in the method of fabricating the anti-fuse, the first conductive type is N-type, whereas the second conductive type is P-type.

According to an embodiment of the present invention, in the method of fabricating the anti-fuse, a step of forming the source/drain regions includes performing a second ion implantation process to form two lightly-doped regions in the substrate. Thereafter, a spacer is formed on a sidewall of the gate structure. Finally, a third ion implantation process is performed to form two heavily-doped regions in the substrate. The two heavily-doped regions and the two lightly-doped regions together construct the two source/drain regions.

According to an embodiment of the present invention, in the method of fabricating the anti-fuse, the second ion implantation process includes a vertical ion implantation process.

According to an embodiment of the present invention, in the method of fabricating the anti-fuse, the second ion implantation process includes a tilt ion implantation process.

According to an embodiment of the present invention, in the method of fabricating the anti-fuse, the two lightly-doped regions formed by the implementation of the tilt ion implantation process are extended below the gate, yet the two lightly-doped regions are not overlapped to each other.

According to an embodiment of the present invention, in the method of fabricating the anti-fuse, the two lightly-doped regions are partially overlapped in the substrate below the gate through the implementation of the tilt ion implantation process.

The present invention further provides a method of programming an anti-fuse. The method is adapted to the anti-fuse including a substrate having a first conductive type, a gate having the first conductive type, a gate dielectric layer, and two source/drain regions having a second conductive type. The gate is disposed over the substrate. The gate dielectric layer is sandwiched between the substrate and the gate. The two source/drain regions are disposed in the substrate at respective sides of the gate. The method of programming the anti-fuse includes firstly applying a voltage to the gate to break down the gate dielectric layer. The gate and the substrate are then electrically conducted or a P/N forward bias is then formed in a P/N junction after the breakdown of the gate dielectric layer.

According to an embodiment of the present invention, in the method of programming the anti-fuse, the first conductive type is P-type, and the second conductive type is N-type. Besides, the voltage applied to the gate is a positive voltage, and the substrate and the two source/drain regions are all grounded.

According to an embodiment of the present invention, in the method of programming the anti-fuse, the first conductive type is N-type, and the second conductive type is P-type. Besides, the voltages applied to the gate and to the substrate are a negative voltage and a positive voltage, respectively, and the two source/drain regions are both grounded.

The gate and the substrate of the anti-fuse have the same conductive type. After the anti-fuse is blown, an extremely low resistance value of the anti-fuse can be accomplished, and it is unlikely to form the high resistive non-linear current path. Thereby, yield of the programmed circuit is raised.

The method of fabricating the anti-fuse is fully compatible with a manufacturing process of a CMOS, and the manufacturing costs are rather low. Besides, it is not necessary to re-design the circuit.

In order to the make the aforementioned and other objects, features and advantages of the present invention comprehensible, several embodiments accompanied with figures are described in detail below.

### BRIEF DESCRIPTION OF THE DRAWINGS

FIG. 1 is a schematic view illustrating an anti-fuse of a conventional N-type channel MOSFET.

FIGS. 2A, 2B and 2C are schematic views respectively illustrating an anti-fuse according to an embodiment of the present invention.

FIGS. 3A to 3E-3 are schematic cross-sectional flowcharts illustrating a method of fabricating an anti-fuse according to an embodiment of the present invention.

FIG. 4 is a schematic circuit diagram of an anti-fuse applied to an NMOS One-Time Programmable (OTP) memory device.

### DESCRIPTION OF EMBODIMENTS

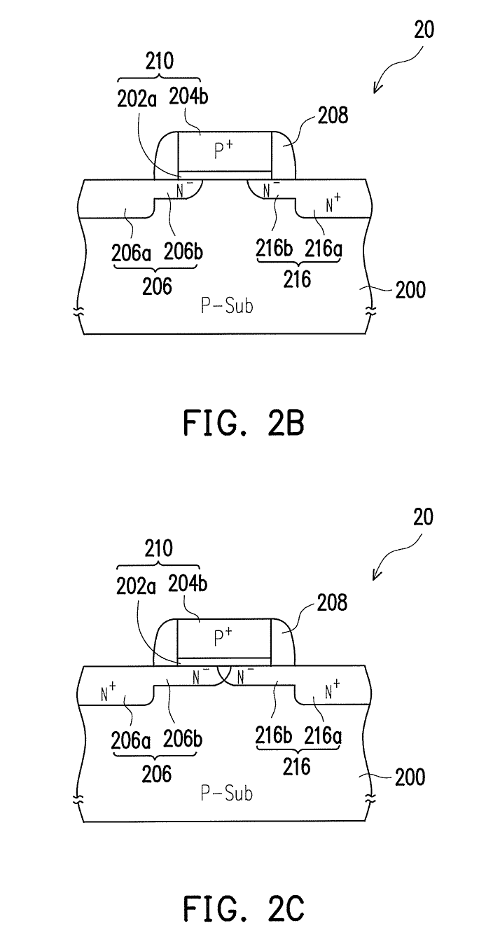

FIGS. 2A, 2B and 2C are schematic views respectively illustrating a gate-oxide anti-fuse according to an embodiment of the present invention.

With reference to FIG. 2A, a gate-oxide anti-fuse 20 in the present embodiment of the present invention is referred to as the anti-fuse 20 hereinafter. The anti-fuse 20 includes a substrate 200, a gate dielectric layer 202a, a gate 204b, source/drain regions 206 and 216, and a spacer 208. The substrate 200 described herein is a semiconductor body, such as a silicon body or a well in the body. The substrate 200 has a first conductive type. Namely, the substrate 200 is a P-type substrate or an N-type substrate, for example. In the drawings, the P-type substrate 200 is illustrated. The gate dielectric layer 202a is disposed on the substrate 200 and is made of silicon oxide or silicon nitride, for example. The gate 204b is disposed on the gate dielectric layer 202a. The gate 204b and the substrate 200 have the same conductive type, i.e. the first conductive type. In the drawings, the P-type gate 204b and the P-type substrate 200 are illustrated. The gate dielectric layer 202a, and the gate 204b together construct a gate structure 210. The spacer 208 is disposed on a sidewall of the gate structure 210 and is made of silicon oxide or silicon nitride. The spacer 208 may be a single-layered spacer, a double-layered spacer or a multi-layered spacer.

The source/drain regions 206 and 216 are disposed in the substrate 200 at respective sides of the gate 204b and have a different conductive type from the gate 204b. That is to say, the source/drain regions 206 and 216 have a second conductive type. In the drawings, the N-type source/drain regions 206 and 216 are illustrated. In one embodiment, the source/drain regions 206 and 216 are composed of heavily-doped regions 206a and 216a and lightly-doped regions 206b and 216b. In one embodiment, the substrate 200 and the gate 204b are P-type, whereas the source/drain regions 206 and 216 are N-type. In another embodiment, however, the substrate 200 and the gate 204b are N-type, whereas the source/drain regions 206 and 216 are P-type.

In one embodiment, the two lightly-doped regions 206b and 216b are not overlapped to each other, as shown in FIGS. 2A and 2B. In FIG. 2A, the two lightly-doped regions 206b and 216b are disposed outside the sidewall of the gate 204b and are not extended below the gate 204b. By contrast, in FIG. 2B, the two lightly-doped regions 206b and 216b are extended below the gate 204b, yet the two lightly-doped regions 206b and 216b are not overlapped to each other. On the other hand, in another embodiment, the two lightly-doped regions 206b and 216b are extended below the gate 204b and partially overlapped, as shown in FIG. 2C.

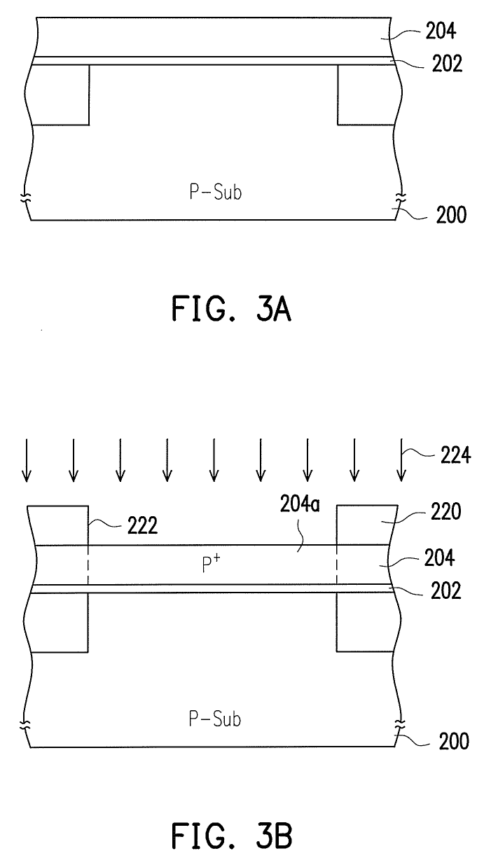

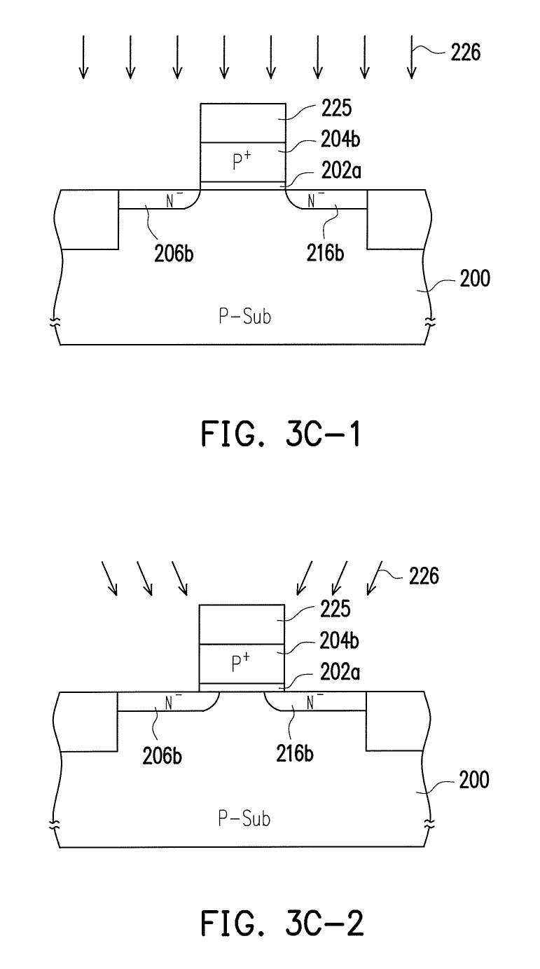

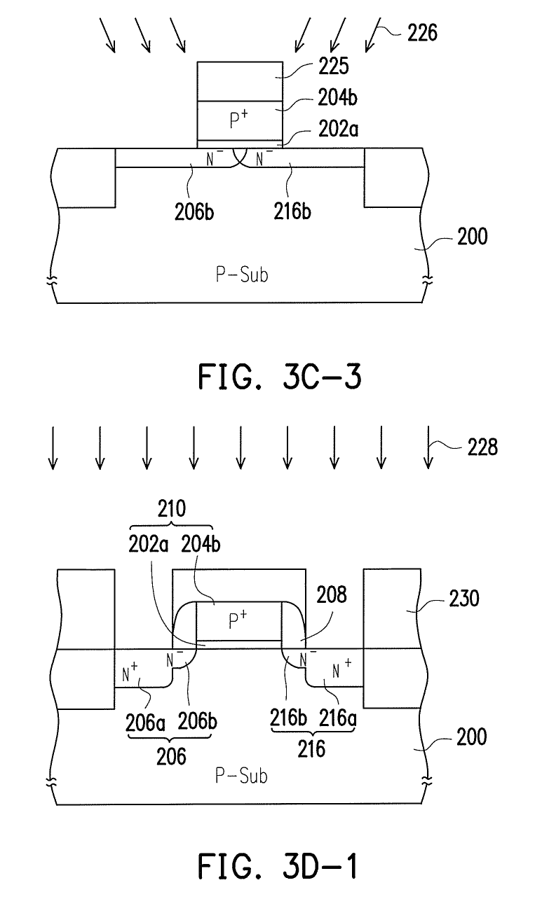

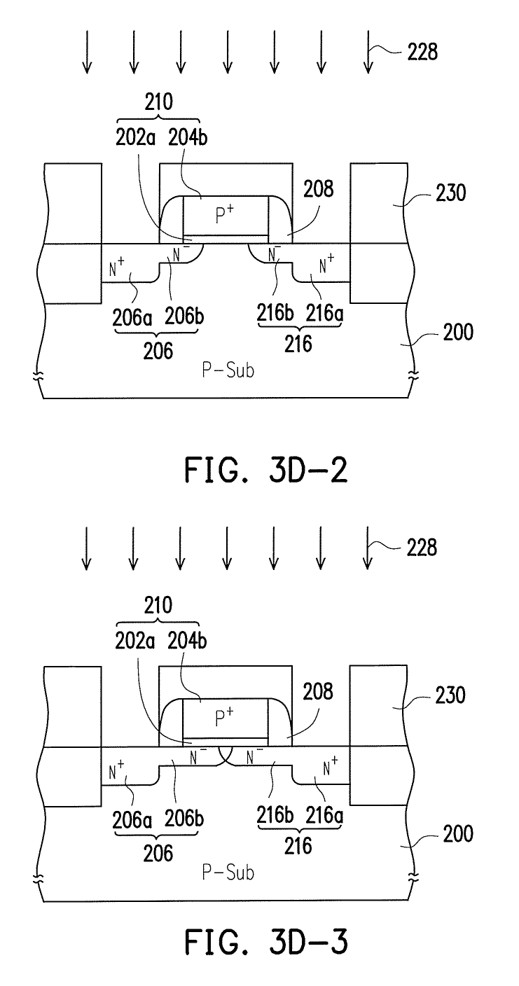

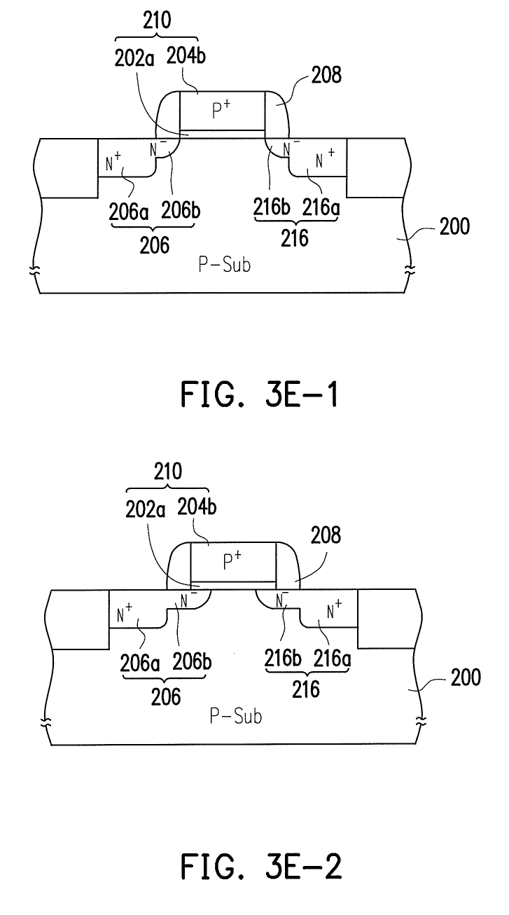

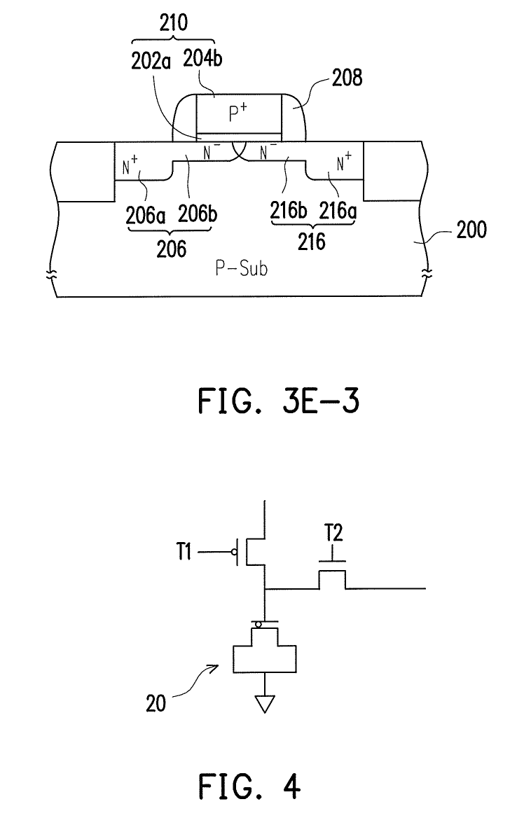

FIGS. 3A to 3E-3 are schematic cross-sectional flowcharts illustrating a method of fabricating an anti-fuse according to an embodiment of the present invention.

Referring to FIG. 3A, a substrate 200 is provided. The substrate 200 has dopants having a first conductive type. Namely, the substrate 200 is a P-type substrate or an N-type substrate, for example. In the drawings, the P-type substrate 200 is illustrated. The substrate 200 described herein is a semiconductor body, such as a silicon body or a well in the body. Then, a dielectric layer 202 and a conductive layer 204 are sequentially formed on the substrate 200. The dielectric layer 202 is made of silicon oxide and is formed by thermal oxidation, for example. Besides, the conductive layer 204 is made of polysilicon or a polycide layer constituted by a polysilicon layer and a metal silicide layer.

After that, referring to FIG. 3B, a mask layer 220 e.g. a photoresist layer is formed on the conductive layer 204. The mask layer 220 has an opening 222 exposing the conductive layer 204 on an area 224 in which the anti-fuse is to be formed. Next, an ion implantation process 224 is performed to implant ions into the conductive layer 204. The ions have the same conductive type, i.e. the first conductive type, as the substrate 200 does. Thereby, a doped conductive layer 204a is formed in the conductive layer 204. As the first conductive type is P-type, the ions implanted into the conductive layer 204a are boron, for example. On the contrary, as the first conductive type is N-type, the dopants implanted into the conductive layer 204a are phosphorus or arsenic, for example. In the drawings, the first conductive type is P-type.

After that, referring to FIG. 3C, the mask layer 220 is removed, and another mask layer 225 is then formed on a portion of the conductive layer 204a. A material of the mask layer 225 is, for example, a photoresist material. Afterwards, an etching process is carried out to remove the conductive layer 204a uncovered by the mask layer 225, the conductive layers 204, and the underlying dielectric layer 202, so as to form a gate 204b and a gate dielectric layer 202a.

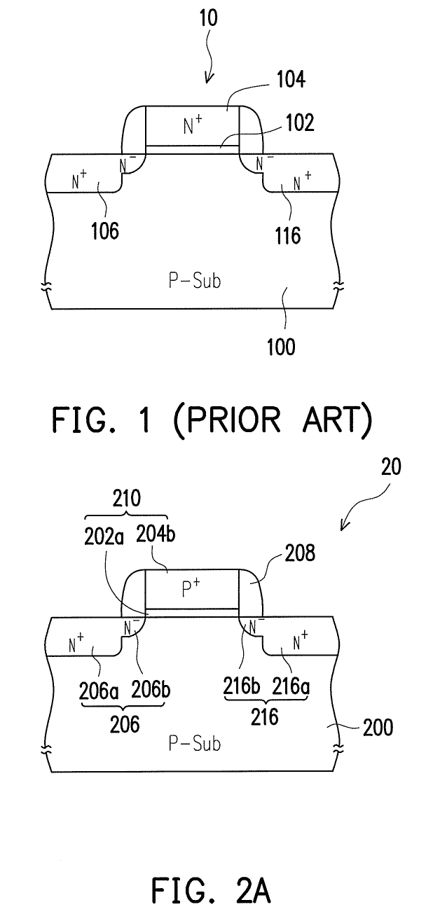

Next, an ion implantation process 226 is implemented to form lightly-doped regions 206b and 216b in the substrate 200. The ions implanted through the ion implantation process 226 have the second conductive type, which is different from that of the gate 204b. As the second conductive type is N-type, the ions implanted into the source/drain regions 206 and 216 are phosphorus or arsenic, for example. On the contrary, as the second conductive type is P-type, the ions implanted into the source/drain regions 206 and 216 are boron, for example. When the ion implantation process 226 is a vertical ion implantation process, the lightly-doped regions 206b and 216b formed thereby are not covered by the gate 204b, as shown in FIG. 3C-1. By contrast, when the ion implantation process 226 is a tilt ion implantation process, the lightly-doped regions 206b and 216b formed thereby are partially extended below the gate 204b but are not overlapped to each other, as shown in FIG. 3C-2. Additionally, when the ion implantation process 226 is the tilt ion implantation process, the lightly-doped regions 206b and 216b formed thereby may also be partially extended below the gate 204b and partially overlapped to each other, as shown in FIG. 3C-3.

Thereafter, with reference to FIGS. 3D-1, 3D-2 and 3D-3, the mask layer 225 is removed. Next, a spacer 208 is formed on a sidewall of the gate 204b. The spacer 208 may be formed by constructing a single-layered material layer, a double-layered material layer, or a multi-layered material layer on the substrate, and a material of the spacer 208 may be selected from silicon oxide or silicon nitride. Then, an anisotropic etching process is performed. After that, another mask layer 230 is formed on the substrate 200, exposing an area in which heavily-doped regions are to be formed. The mask layer 230 is a photoresist layer, for example. Next, another ion implantation process 228 is carried out to form heavily-doped regions 206a and 216a in the substrate 200. The heavily-doped region 206a and the lightly-doped region 206b together construct the source/drain region 206, whereas the heavily-doped region 216a and the lightly-doped region 216b together form the source/drain region 216.

Thereafter, referring to FIGS. 3E-1, 3E-2 and 3E-3, the mask layer 230 is removed. The fabrication of the anti-fuse is then completed.

According to the above embodiments, the lightly-doped regions in the source/drain regions are firstly formed, and the heavily-doped regions are subsequently constructed. Nevertheless, the present invention should not be construed as limited to the embodiments set forth herein. In the present invention, it is also likely to form the heavily-doped regions in the source/drain regions at first, and then the lightly-doped regions are constructed in need of satisfying actual manufacturing requirements.

The method of fabricating the anti-fuse is fully compatible with a manufacturing process of a CMOS, the manufacturing costs are relatively low, and it is not necessary to re-design the circuit.

Besides, the anti-fuse structure described in the aforesaid embodiments is a transistor having a body channel. In one embodiment, the substrate and the gate are P-type, yet the two doped regions are N-type. During a programming operation, a positive voltage is applied to the gate, and the substrate and the two doped regions are grounded. By contrast, in another embodiment, the substrate and the gate are N-type, yet the two doped regions are P-type. During the programming operation, a negative voltage and the positive voltage are respectively applied to the gate and to the substrate, and the two doped regions are grounded.

FIG. 4 is a schematic circuit diagram of an anti-fuse applied to an NMOS OTP memory device. The source/drain regions of the anti-fuse 20 are grounded. Thick-gate I/O transistors T1 and T2 are adopted to control a programming pulse applied to the anti-fuse 20. As the thick-gate I/O transistors T1 and T2 are turned on and the programming pulse at 4˜7V are applied to the gate of the anti-fuse 20, for example, an open circuit is formed before the anti-fuse is blown. After the anti-fuse is blown, an extremely low resistance value in a range of 5-25 K ohm is achieved in the anti-fuse. The method of programming the anti-fuse in the present invention is identical to the anti-fuse utilized for programming the surface channel transistor in related art. In other words, a voltage is applied to the gate to break down the gate dielectric layer. However, in the present invention, the gate and the substrate have the same conductive type. Accordingly, after the gate dielectric layer is broken down and the pinholes are punched in the gate dielectric layer above the channel, no P-N junction is going to be formed between the gate and the substrate both having the same conductive type. As such, the high resistive non-linear current path is not constructed. Although the pinholes are formed in the gate dielectric layer positioned at source/drain terminals, a P/N forward bias is generated, resulting in a low resistive linear current path which can be detected by the sense amplifier. Thereby, yield of the OTP devices can be effectively improved.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A method of fabricating an anti-fuse, comprising:
forming a dielectric layer on a substrate having a first conductive type;
forming a conductive layer on the dielectric layer;
performing a first ion implantation process to make the conductive layer have the first conductive type;
patterning the conductive layer and the dielectric layer to form a gate and a gate dielectric layer, wherein the gate and the gate dielectric layer together construct a gate structure; and
forming two source/drain regions having a second conductive type and disposed in the substrate at respective sides of the gate.

2. The method according to claim 1, wherein the first conductive type is P-type and the second conductive type is N-type.

3. The method according to claim 1, wherein the first conductive type is N-type and the second conductive type is P-type.

4. The method according to claim 1, wherein a step of forming the two source/drain regions comprises:
performing a second ion implantation process to form two lightly-doped regions in the substrate;
forming a spacer on a sidewall of the gate structure; and
performing a third ion implantation process to form two heavily-doped regions in the substrate, wherein the two heavily-doped regions and the two lightly-doped regions together construct the two source/drain regions.

5. The method according to claim 1, wherein the second ion implantation process comprises a vertical ion implantation process.

6. The method according to claim 1, wherein the second ion implantation process comprises a tilt ion implantation process.

7. The method according to claim 6, wherein the two lightly-doped regions formed by the implementation of the tilt ion implantation process are extended below the gate, yet the two lightly-doped regions are not overlapped to each other.

8. The method according to claim 5, wherein the two lightly-doped regions formed by the implementation of the tilt ion implantation process are partially overlapped in the substrate below the gate.

9. A method of programming an anti-fuse, the anti-fuse comprising:
a substrate having a first conductive type;
a gate having the first conductive type and disposed over the substrate;
a dielectric layer sandwiched between the substrate and the gate; and
two source/drain regions having a second conductive type and respectively disposed in the substrate at respective sides of the gate, the method of programming the anti-fuse comprising:
applying a voltage to the gate to break down the gate dielectric layer, wherein the gate and the substrate are electrically conducted or a P/N forward bias is formed in a P/N junction after the breakdown of the gate dielectric layer.

10. The method according to claim 9, wherein the first conductive type is P-type, the second conductive type is N-type, the voltage applied to the gate is a positive voltage, and the substrate and the two source/drain regions are all grounded.

11. The method according to claim 9, wherein the first conductive type is N-type, the second conductive type is P-type, the voltages applied to the gate and to the substrate are a negative voltage and a positive voltage, respectively, and the two source/drain regions are both grounded.
